(19) United States
(12) Patent Application Publication
(10) Pub. No.: US 2025/0374524 A1
(43) Pub. Date: Dec. 4, 2025

(54) SEMICONDUCTOR DEVICE

(71) Applicant: SAMSUNG ELECTRONICS CO., LTD., Suwon-si (KR)

(72) Inventors: Hoseok Lee, Suwon-si (KR); Chulkwon Park, Suwon-si (KR); Sunggyeong Lee, Suwon-si (KR); Young Seok Park, Suwon-si (KR); Hyun-Chul Yoon, Suwon-si (KR)

(21) Appl. No.: 19/011,391

(22) Filed: Jan. 6, 2025

(30) Foreign Application Priority Data
May 29, 2024 (KR) 10-2024-0070224

(51) Int. Cl. H10B 12/00

(52) U.S. Cl. CPC H10B 12/33; H10B 12/50

(57) ABSTRACT

A semiconductor device includes a cell structure, and a peripheral circuit structure disposed on the cell structure. The cell structure includes a first substrate having a cell array region, data storage patterns spaced apart from each other on the cell array region, word lines on the data storage patterns, and spaced apart from each other, and bit lines crossing the word lines on the word lines. The peripheral circuit structure includes a first region overlapping the cell array region and a second region spaced apart from the first region, first and second transistors, on the first region, disposed on one surface of the second substrate, and a first penetration electrode disposed between the first and second transistors, and vertically extending through the second substrate on the first region to be electrically connected to the bit lines. The first transistors and the second transistors have different conductivity type channel regions.

### CROSS-REFERENCE TO RELATED APPLICATION(S)

This U.S. non-provisional patent application claims priority under 35 U.S.C. § 119 of Korean Patent Application No. 10-2024-0070224, filed on May 29, 2024, the entire contents of which are hereby incorporated by reference.

### BACKGROUND

A semiconductor device is attracting attention as an important component in the electronics industry due to characteristics thereof such as miniaturization, multi-functionality, and/or low manufacturing cost. The semiconductor device may be classified into a semiconductor memory device that stores a logic data, a semiconductor logic device that calculates and processes the logic data, and a hybrid semiconductor device that includes a memory component and a logic component.

Recently, with a high speed and low power consumption of an electronic apparatus, a high operation speed and/or a low operation voltage are/is also required for the semiconductor device built therein. In order to satisfy such requirements, a more highly-integrated semiconductor device is needed. However, when the semiconductor device becomes more highly-integrated, electrical characteristics and production yield of the semiconductor device may be deteriorated or reduced.

As a design rule of the semiconductor device decreases, manufacturing technology thereof is developing in a direction in which an integration density, an operation speed, and yield of the semiconductor device are improved. Accordingly, a transistor having a vertical channel is proposed so as to improve an integration density, resistance, current driving ability, etc., thereof.

### SUMMARY

The present disclosure provides a semiconductor device with a small size, and improved electrical characteristics.

This disclosure provides a semiconductor device including a cell structure, and a peripheral circuit structure disposed on the cell structure. The cell structure includes: a first substrate having a cell array region; on the cell array region, data storage patterns spaced apart from each other in a first direction and a second direction, the first direction and the second direction being parallel to an upper surface of the first substrate and crossing each other; word lines extending in the second direction on the data storage patterns, and spaced apart from each other in the first direction; and bit lines on the word lines, the bit lines crossing the word lines, and extending in the first direction and spaced apart from each other in the second direction. The peripheral circuit structure includes: a second substrate having a first region and a second region spaced apart from the first region, the first region overlapping the cell array region; first and second transistors, on the first region, disposed on one surface of the second substrate; and a first penetration electrode disposed between the first and second transistors, and vertically extending through the second substrate on the first region to be electrically connected to the bit lines. And the first transistors and the second transistors have different conductivity type channel regions.

This disclosure provides a semiconductor device which includes a cell structure, and a peripheral circuit structure disposed on the cell structure. The cell structure includes: a first substrate; data storage patterns on the first substrate, spaced apart from each other in a first direction and a second direction, the first direction and the second direction being parallel to an upper surface of the first substrate and crossing each other; word lines extending in the second direction on the data storage patterns, and spaced apart from each other in the first direction; and bit lines on the word lines, the bit lines crossing the word lines, and extending in the first direction and spaced apart from each other in the second direction. The peripheral circuit structure includes: a second substrate; a first transistor and a second transistor disposed on a surface of the second substrate; a first penetration electrode disposed between the first and second transistors, and vertically extending through the second substrate to be electrically connected to the bit lines; and a spacer interposed between the second substrate and the first penetration electrode. The first transistor: includes an impurity region formed so as to be in contact with the one surface of the second substrate in the second substrate; and first source/drain regions formed in the impurity region. And the first penetration electrode is spaced apart from the impurity region.

This disclosure provides a semiconductor device includes a cell structure, and a peripheral circuit structure disposed on the cell structure. The cell structure includes: a first substrate having a cell array region; a plurality of data storage patterns on the cell array region, spaced apart from each other in a horizontal direction; semiconductor patterns on the data storage patterns, the semiconductor patterns extending in a direction vertical to an upper surface of the first substrate; word lines disposed on the cell array region, and disposed adjacent to the semiconductor patterns on the data storage patterns; gate insulating patterns respectively interposed between the word lines and the semiconductor patterns; and bit lines disposed on the cell array region and on the word lines, the bit lines crossing the word lines and connecting to the semiconductor patterns. The peripheral circuit structure includes: a second substrate having a core region overlapping the cell array region; a first transistor and a second transistor on the core region, disposed on a surface of the second substrate; and a peripheral circuit line disposed on the second substrate, and connecting the first transistor and the second transistor. The first transistor includes an impurity region formed in the second substrate so as to be in contact with the surface of the second substrate, and first source/drain regions formed in the impurity region. The second transistor includes second source/drain regions formed in the second substrate, and disposed so as to be spaced apart from the impurity region. And the peripheral circuit structure further includes a first penetration electrode connected to the peripheral circuit line between the first transistor and second the transistor, and vertically extending through the second substrate to be electrically connected to the bit lines.

### BRIEF DESCRIPTION OF THE DRAWINGS

FIG. 1 is a block diagram for describing a semiconductor device according to implementations;

FIG. 2 is a perspective view schematically illustrating a semiconductor device according to implementations;

FIG. 3 is a plan view for describing a semiconductor device according to implementations;

FIGS. 4 and 5 are cross-sectional views taken along line A-A′ and line B-B′ of FIG. 3, respectively;

FIGS. 6 to 12 are schematic plan views for describing arrangement of penetration electrodes and transistors of a peripheral circuit structure; and

FIGS. 13 and 14 are cross-sectional views for describing a semiconductor device according to implementations.

### DETAILED DESCRIPTION

A semiconductor device according to the inventive concept will be described with reference to the drawings.

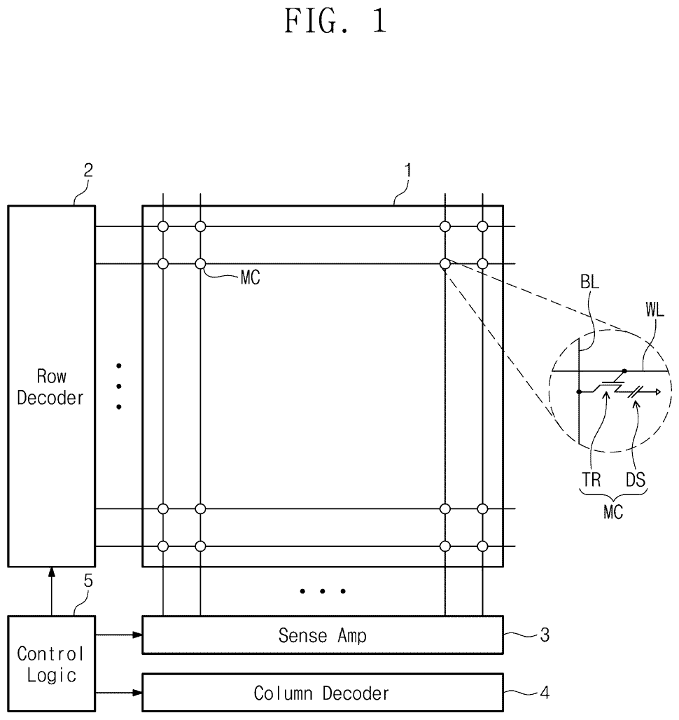

FIG. 1 is a block diagram for describing the semiconductor device according to implementations.

Referring to FIG. 1, the semiconductor device may include a memory cell array 1, a row decoder 2, a sense amplifier 3, a column decoder 4, and a control logic 5.

The memory cell array 1 may include a plurality of memory cells MC two-dimensionally or three-dimensionally arranged. Each of the memory cells MC may be connected between a word line WL and a bit line BL crossing each other.

Each of the memory cells MC may include a selection element TR and a data storage element DS. The selection element TR and the data storage element DS may be electrically connected to each other. The selection element TR may be connected to all of the word line WL and the bit line BL. In other words, the selection element TR may be provided at a point at which the word line WL and the bit line BL cross each other.

The selection element TR may include a field effect transistor. The data storage element DS may include a capacitor, a magnetic tunnel junction pattern, or a variable resistor. For example, a gate terminal of a transistor, which is the selection element TR, may be connected to the word line WL, and source/drain terminals of the transistor may be respectively connected to the bit line BL and the data storage element DS.

The row decoder 2 may select any one of the word lines WL of the memory cell array 1 by decoding an address input from the outside thereof. The address decoded by the row decoder 2 may be supplied to a row driver (not shown), and the row driver may supply a predetermined voltage to a selected word line WL and unselected word lines WL in response to a control of control circuits.

The sense amplifier 3 may sense and amplify a voltage difference between a selected bit line BL and a reference bit line according to the address decoded by the column decoder 4, and may output the voltage difference.

The column decoder 4 may supply a data transmission path between the sense amplifier 3 and an external device (for example, a memory controller). The column decoder 4 may select any one of the bit lines BL by decoding an address input from the outside thereof.

The control logic 5 may generate a control signal that controls an operation of writing a data to or reading a data from the memory cell array 1.

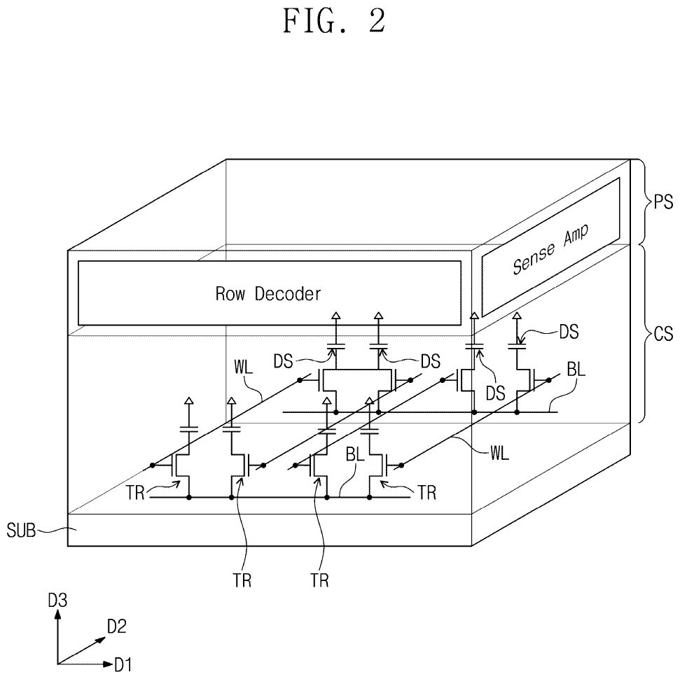

FIG. 2 is a perspective view schematically illustrating a semiconductor device according to implementations.

Referring to FIG. 2, the semiconductor device may include a cell structure CS and a peripheral circuit structure PS connected to the cell structure CS.

The cell structure CS may be provided on a substrate SUB, and the peripheral circuit structure PS may be provided on the cell structure CS.

The cell structure CS may include the memory cell array 1 (see FIG. 1) including the memory cells MC (see FIG. 1) formed on the substrate SUB. The memory cells MC (see FIG. 1) may be two-dimensionally or three-dimensionally arranged on the substrate SUB. As described above, each of the memory cells MC (see FIG. 1) may include the selection element TR and the data storage element DS.

According to some implementations, the selection element TR of each of the memory cells MC (see FIG. 1) may include a vertical channel transistor VCT. The vertical channel transistor may include a channel of which a lengthwise direction is a direction vertical to an upper surface of the substrate SUB. The data storage element DS of each of the memory cells MC (see FIG. 1) may include a capacitor.

The peripheral circuit structure PS may include a core and peripheral circuits formed on the substrate SUB. The core and peripheral circuits may include the row and column decoders 2 and 4, the sense amplifier 3 and the control logic 5 described with reference to FIG. 1.

The peripheral circuit structure PS may be electrically connected to the memory cell array 1 (see FIG. 1) of the cell structure CS. The cell structure CS may be electrically connected to the core and peripheral circuits 2, 3, 4, and 5 (see FIG. 1) of the peripheral circuit structure PS.

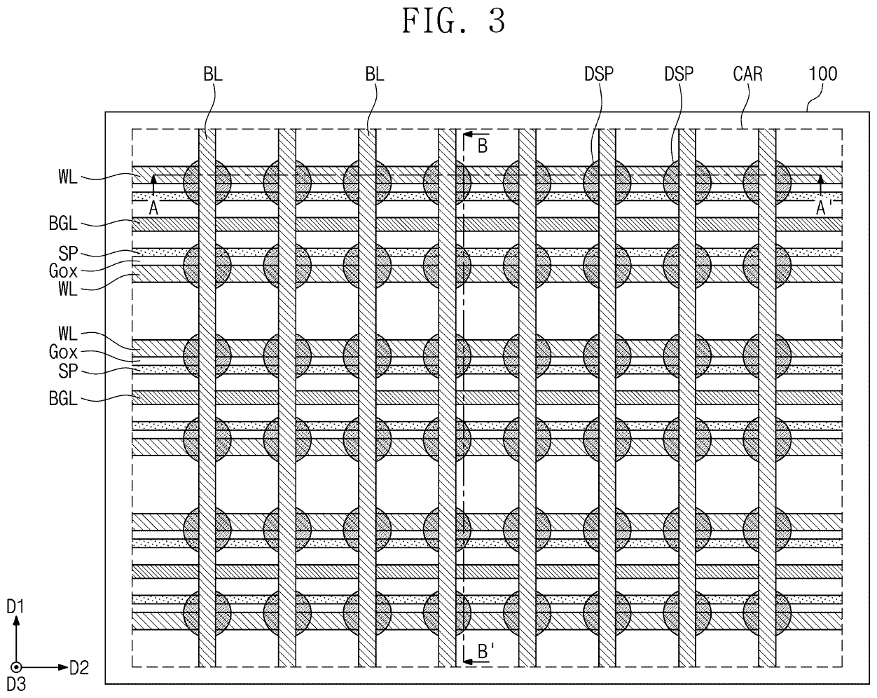

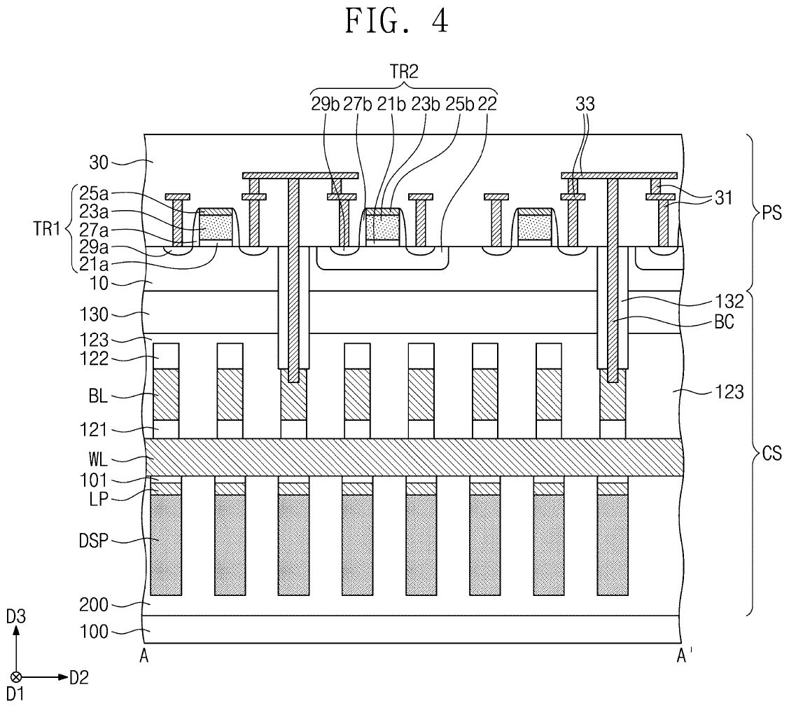

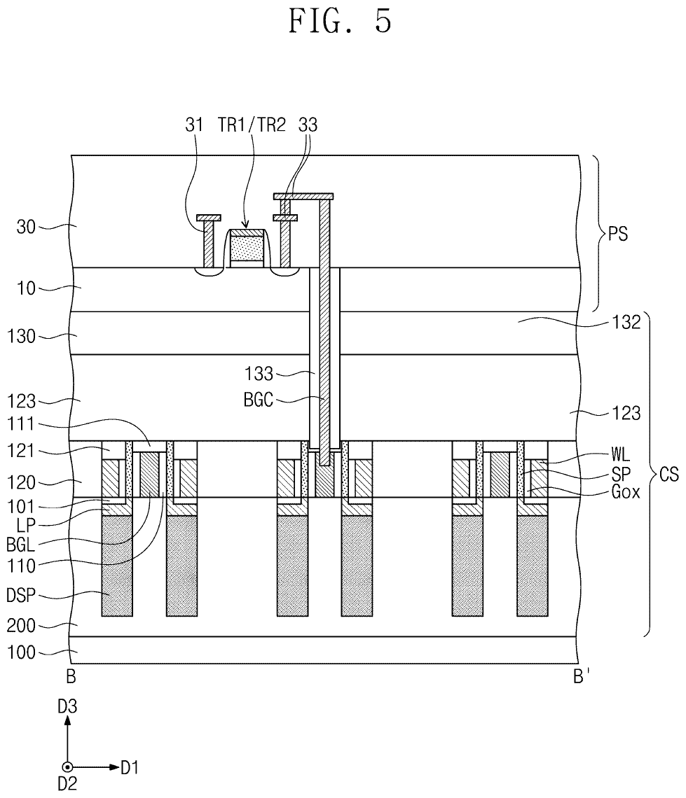

FIG. 3 is a plan view for describing a semiconductor device according to implementations. FIGS. 4 and 5 are cross-sectional views taken along line A-A′ and line B-B′ of FIG. 3, respectively.

Referring to FIGS. 3, 4, and 5, a cell structure CS may be provided on a substrate 100 including a cell array region CAR. The cell structure CS may include a lower insulating film 200 disposed on the cell array region CAR of the substrate 100. The lower insulating film 200 may extend in a first direction D1 and a second direction D2. As used herein, the first direction D1 and the second direction D2 may be defined as directions parallel to an upper surface of the substrate 100 and crossing each other. The first direction D1 and the second direction D2 may be referred to as horizontal directions D1 and D2. A third direction D3 may be a direction vertical to the upper surface of the substrate 100. For example, the first direction D1, the second direction D2, and the third direction D3 may be directions perpendicular to each other. In some implementations, the lower insulating film 200 may include a plurality of stacked insulating films. For example, the lower insulating film 200 may include an insulating material such as silicon oxide, silicon nitride, silicon oxynitride, and/or a low dielectric material.

Data storage patterns DSP may be disposed in the cell array region CAR of the lower insulating film 200. The data storage patterns DSP may be spaced apart from each other in the first direction D1 and the second direction D2. The lower insulating film 200 may cover the data storage patterns DSP. The lower insulating film 200 may fill a space between the data storage patterns DSP, and may be in contact with the upper surface of the substrate 100.

According to some implementations, the data storage patterns DSP may be a capacitor and may include lower and upper electrodes, and a capacitor dielectric film interposed therebetween. In this case, the lower electrode may be in contact with a landing pad LP, and may have various forms such as a circle, an ellipsoid, a rectangle, a square, a rhombus, a hexagon, or the like in a plan view.

Alternatively, the data storage patterns DSP may be a variable resistance pattern capable of being switched to two resistance states by an electrical pulse applied to a memory component. For example, the data storage patterns DSP may include a phase-change material changing a crystalline state depending on an amount of current, a perovskite compound, a transition metal oxide, a magnetic material, a ferromagnetic material, or an antiferromagnetic material.

The landing pad LP and a first capping pattern 101 may be disposed on the data storage pattern DSP. The landing pad LP may be in contact with the data storage pattern DSP and may be in contact with a semiconductor pattern SP to be described later. The first capping pattern 101 may be disposed on the landing pad LP and may be disposed on a lower surface of a word line WL to be described later. For example, the landing pad LP may be composed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but implementations are not limited thereto. For example, the first capping pattern 101 may include at least one of silicon oxide, silicon nitride, or silicon oxynitride.

The word line WL may be disposed on the lower insulating film 200. The word line WL may be provided in plurality. In addition, the word line WL may be disposed on the data storage pattern DSP. The first capping pattern 101 may be interposed between the word line WL and the data storage pattern DSP. The word lines WL may extend in the second direction D2, and may be spaced apart from each other in the first direction D1. In a plan view, the data storage patterns DSP may vertically overlap the corresponding word lines WL respectively.

A back-gate line BGL may be disposed on the lower insulating film 200. The back-gate line BGL may be provided in plurality, and the back-gate lines BGL may extend in the second direction D2 and may be spaced apart from each other in the first direction D1. The back-gate line BGL may be disposed between the word lines WL. Specifically, each of the back-gate lines BGL may be disposed between a pair of word lines WL among the word lines WL spaced apart from each other in the first direction D1.

For example, the word lines WL and the back-gate lines BGL may be composed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSIN, RuTiN, NiSi, CoSi, IrOx, RuOx, or a combination thereof, but implementations are not limited thereto.

The semiconductor pattern SP may be disposed on the lower insulating film 200. The semiconductor pattern SP may be provided in plurality, and the semiconductor patterns SP may extend in the second direction D2 and may be spaced apart from each other in the first direction D1. Each of the semiconductor patterns SP may be respectively disposed on one side of the corresponding word lines WL. The semiconductor pattern SP may be disposed between the word line WL and the back-gate line BGL. For example, the pair of word lines WL among the word lines WL spaced apart from each other in the first direction D1 may be disposed in a direction facing the semiconductor pattern SP. The word line WL may be disposed on one side of the semiconductor pattern SP, and the back-gate line BGL may be disposed on the other side of the semiconductor pattern SP. The semiconductor pattern SP may be disposed on both sides of the back-gate line BGL. The back-gate line BGL may be disposed between the adjacent semiconductor patterns SP facing each other.

The semiconductor pattern SP may have a vertical channel structure in which a channel length thereof extends in the third direction D3. A lower surface of each of the semiconductor patterns SP may be in contact with the corresponding landing pad LP. That is, each of the semiconductor pattern SP may be electrically connected to the landing pad LP. For example, the semiconductor pattern SP may be composed of silicon doped with a dopant. In another example, the semiconductor pattern SP may include an oxide semiconductor. For example, the oxide semiconductor may include at least one of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, or InₓGa_{y}O, but implementations are not limited thereto. For example, the semiconductor pattern SP may include indium gallium zinc oxide (IGZO). The semiconductor pattern SP may include a single-layer or multi-layer of the oxide semiconductor.

A gate insulating pattern Gox may be disposed on the lower insulating film 200, and may be interposed between the word line WL and the semiconductor pattern SP. The gate insulating pattern Gox may be provided in plurality, and the gate insulating patterns Gox may extend in the second direction D2 and may be spaced apart from each other in the first direction D1. The word line WL may be spaced apart from the corresponding semiconductor pattern SP with the gate insulating pattern Gox therebetween. The gate insulating pattern Gox may be composed of a silicon oxide film, a silicon oxynitride film, a high dielectric film having a higher dielectric constant than the silicon oxide film, or a combination thereof. The high dielectric film may be composed of a metal oxide, or metal oxynitride. For example, the high dielectric film may include HfO₂, HfSiO, HfSiON, HfTaO, HfTiO, HfZrO, ZrO₂, Al₂O₃, or a combination thereof.

A second capping pattern 121 may be disposed on the word line WL and the gate insulating pattern Gox. The second capping pattern 121 may be provided in plurality, and the second capping patterns 121 may be disposed on the corresponding word lines WL and the corresponding gate insulating patterns Gox. The semiconductor pattern SP may extend to the same level as an upper surface of the second capping pattern 121 in the third direction D3. That is, the upper surface of the second capping pattern 121 and the upper surface of the semiconductor pattern SP may be coplanar with each other. The upper surface of the semiconductor pattern SP may be located at a higher level than upper surfaces of the word line WL and the gate insulating pattern Gox. For example, the second capping pattern 121 may include at least one of silicon oxide, silicon nitride, or silicon oxynitride.

Back-gate insulating patterns 110 may be disposed on the lower insulating film 200, and on both side surfaces of each of the back-gate lines BGL. The back-gate insulating patterns 110 may be respectively interposed between the back-gate line BGL and the semiconductor patterns SP adjacent thereto. The back-gate line BGL may be spaced apart from the semiconductor pattern SP with the back-gate insulating patterns 110 therebetween. The back-gate insulating pattern 110 may be composed of a silicon oxide film, a silicon oxynitride film, and a high dielectric film having a higher dielectric constant than the silicon oxide film, or a combination thereof. The high dielectric film may be composed of a metal oxide, or metal oxynitride. For example, the high dielectric film may include HfO₂, HfSiO, HfSiON, HfTaO, HfTiO, HfZrO, ZrO₂, Al₂O₃, or a combination thereof.

A back-gate capping pattern 111 may be disposed on the back-gate line BGL and on the back-gate insulating patterns 110 of both side surfaces of the back-gate line BGL. The back-gate capping pattern 111 may be disposed between adjacent semiconductor patterns SP facing each other. An upper surface of the back-gate capping pattern 111 may be coplanar with the upper surface of the semiconductor pattern SP. For example, the back-gate capping pattern 111 may include at least one of silicon oxide, silicon nitride, or silicon oxynitride.

A first insulating pattern 120 may be disposed on the lower insulating film 200. The first insulating pattern 120 may be provided in plurality. The first insulating pattern 120 may be disposed between the word lines WL facing each other. That is, the semiconductor pattern SP may be disposed on one side of each of the word lines WL, and the first insulating pattern 120 may be disposed on the other side thereof. The first insulating patterns 120 may extend in the second direction D2, and may be spaced apart from each other in the first direction D1. An upper surface of the first insulating pattern 120 may be coplanar with upper surfaces of the second capping pattern 121, the semiconductor pattern SP, and the back-gate capping pattern 111. For example, the first insulating pattern 120 may include at least one of silicon oxide, silicon nitride, silicon oxynitride, or a low dielectric material. For example, the first insulating pattern 120 may be composed of a single-layer or multi-layer.

A bit line BL may be disposed on the first insulating patterns 120, the word lines WL, the back-gate lines BGL, the semiconductor patterns SP, the gate insulating patterns Gox, the back-gate insulating patterns 110, the second capping patterns 121, and the back-gate capping patterns 111. The bit line BL may extend in a direction crossing the word lines WL, that is, in the first direction D1. The bit line BL may be provided in plurality, and the bit lines BL may be spaced apart from each other in the second direction D2. The bit line BL may be in contact with upper surfaces of the corresponding semiconductor patterns SP. That is, the semiconductor patterns SP may be electrically connected to the bit line BL. In a plan view, the bit lines BL may vertically overlap the corresponding data storage patterns DSP. For example, the bit line BL may include at least one of doped polysilicon, metal (for example, Al, Cu, Ti, Ta, Ru, W, Mo, Pt, Ni, or Co), a conductive metal nitride (for example, TiN, TaN, WN, NbN, TiAlN, TiSiN, TaSiN, or RuTiN), a conductive metal silicide, or a conductive metal oxide (for example, PtO, RuO₂, IrO₂, SRO (SrRuO₃), BSRO ((Ba,Sr)RuO₃), CRO (CaRuO₃), or LSCO), but implementations are not limited thereto. The bit line BL may include a single-layer or multi-layer of the materials described above. According to some implementations, the bit line BL may include a two-dimensional semiconductor material, for example, graphene, carbon nanotube, or a combination thereof.

A capping layer 122 may be disposed on the bit line BL. For example, the capping layer 122 may include at least one of silicon oxide, silicon nitride, silicon oxynitride, or a low dielectric material.

A second insulating pattern 123 covering the bit line BL may be disposed. The second insulating pattern 123 may conformally cover the second capping pattern 121, the bit line BL, and the capping layer 122, and may extend onto the word line WL. For example, the second insulating pattern 123 may include at least one of silicon oxide, silicon nitride, silicon oxynitride, or a low dielectric material.

A first interlayer insulating film 130 may be disposed on the second insulating pattern 123. The first interlayer insulating film 130 may cover the second insulating pattern 123. For example, the first interlayer insulating film 130 may include at least one of silicon oxide, silicon nitride, silicon oxynitride or a low dielectric material.

A peripheral circuit structure PS may be disposed on the cell structure CS.

The peripheral circuit structure PS may include peripheral circuit transistors TR1 and TR2 on an upper surface of a peripheral substrate 10, peripheral contact plugs 31, peripheral circuit lines 33 electrically connected to the peripheral circuit transistors TR1 and TR2 through the peripheral contact plugs 31, and a peripheral circuit insulating film 30 surrounding the same. The peripheral circuit transistors TR1 and TR2, the peripheral contact plugs 31, and the peripheral circuit lines 33 may constitute a peripheral circuit. The peripheral circuit transistors TR1 and TR2 may be located on the cell array region CAR of the cell structure CS, more specifically, on memory cells. The peripheral circuit transistors TR1 and TR2 may include first peripheral circuit transistors TR1 and second peripheral circuit transistors TR2.

Each of the first peripheral circuit transistors TR1 may include a first peripheral gate insulating film 21a, a first peripheral gate electrode 23a, a first peripheral capping pattern 25a, a first peripheral gate spacer 27a, and first peripheral source/drain regions 29a.

The first peripheral gate insulating film 21a may be disposed between the first peripheral gate electrode 23a and the peripheral substrate 10. The first peripheral capping pattern 25a may be disposed on the first peripheral gate electrode 23a. The first peripheral gate spacer 27a may cover sidewalls of the first peripheral gate insulating film 21a, the first peripheral gate electrode 23a, and the first peripheral capping pattern 25a. The first peripheral source/drain regions 29a may be provided inside the peripheral substrate 10 adjacent to both sides of the first peripheral gate electrode 23a.

Each of the second peripheral circuit transistors TR2 may include an impurity region 22, a second peripheral gate insulating film 21b, a second peripheral gate electrode 23b, a second peripheral capping pattern 25b, a second peripheral gate spacer 27b, and second peripheral source/drain regions 29b.

The impurity region 22 may be provided on the peripheral substrate 10. The impurity region 22 may be exposed onto an upper surface of the peripheral substrate 10. The impurity region 22 may have a different conductivity type from the peripheral substrate 10. For example, the peripheral substrate 10 may have a P-type, and the impurity region 22 may have an N-type. Alternatively, for example, the peripheral substrate 10 may have the N-type, and the impurity region 22 may have the P-type. The second peripheral gate insulating film 21b may be disposed between the second peripheral gate electrode 23b and the impurity region 22. The second peripheral capping pattern 25b may be disposed on the second peripheral gate electrode 23b. The second peripheral gate spacer 27b may cover sidewalls of the second peripheral gate insulating film 21b, the second peripheral gate electrode 23b, and the second peripheral capping pattern 25b. The second peripheral source/drain regions 29b may be provided inside the impurity region 22 adjacent to both sides of the second peripheral gate electrode 23b.

The first peripheral circuit transistors TR1 and the second peripheral circuit transistors TR2 may have different conductivity type channel regions. For example, the first peripheral source/drain regions 29a of the first peripheral circuit transistors TR1 may be formed in the peripheral substrate 10, and the second peripheral source/drain regions 29b of the second peripheral circuit transistors TR2 may be formed in the impurity region 22 having a different conductivity type from the peripheral substrate 10. A first peripheral circuit transistor TR1 may be one of an NMOS or PMOS, and a second peripheral circuit transistor TR2 may be the other of the NMOS or PMOS.

The peripheral circuit lines 33 may be electrically connected to peripheral circuit transistors PTR through the peripheral contact plugs 31. More specifically, a pair of the first peripheral circuit transistor TR1 and the second peripheral circuit transistor TR2 adjacent to each other may be connected to each other through the peripheral contact plugs 31 and the peripheral circuit lines 33. The pair of the first and second peripheral circuit transistors TR1 and TR2 may constitute a CMOS device. The peripheral contact plugs 31 and the peripheral circuit lines 33 may include a conductive material such as metal.

The peripheral circuit insulating film 30 may be provided on an upper surface of the peripheral substrate 10. The peripheral circuit insulating film 30 may cover, on the peripheral substrate 10, the first and second peripheral circuit transistors TR1 and TR2, the peripheral contact plugs 31, and the peripheral circuit lines 33. The peripheral circuit insulating film 30 may include a plurality of insulating films having a multi-layered structure. For example, the peripheral circuit insulating film 30 may include silicon oxide, silicon nitride, silicon oxynitride, and/or a low dielectric material.

A bit line contact BC extending through the peripheral substrate 10, the first interlayer insulating film 130, and the capping layer 122, and partially extending through the second insulating pattern 123 to be connected to the bit line BL may be disposed. Unlike what is illustrated, a width of the bit line contact BC in the horizontal direction D1 or D2 may increase in a vertical direction D3 getting farther from the substrate 100. A lower surface of the bit line contact BC may be lower than an upper surface of the bit line BL. The bit line contact BC may be provided in plurality, and the bit line contacts BC may be respectively connected to the corresponding bit lines BL. The bit line contacts BC may be disposed on the cell array region CAR of the substrate 100. In a plan view, the bit line contacts BC may vertically overlap the data storage patterns DSP. Alternatively, the bit line contact BC may vertically overlap a region between the data storage patterns DSP without vertically overlapping the data storage pattern DSP. That is, the bit line contacts BC may be disposed in a region vertically overlapping a region in which the data storage patterns DSP are present in an array form. In addition, each of the bit line contacts BC may be located between a pair of the first peripheral circuit transistor TR1 and the second peripheral circuit transistor TR2 electrically connected to each other, that is, forming a CMOS device. For example, when as in FIG. 4, the pair of the first peripheral circuit transistor TR1 and the second peripheral circuit transistor TR2 are arranged along the second direction D2, the bit line contact BC may be located between the first peripheral circuit transistor TR1 and the second peripheral circuit transistor TR2 in the second direction D2. The bit line contact BC may vertically overlap the peripheral circuit line 33 connecting the pair of the first peripheral circuit transistor TR1 and the second peripheral circuit transistor TR2. Each of the bit line contacts BC may extend through the peripheral circuit insulating film 30 to be connected to the peripheral circuit lines 33 connecting the pair of the first peripheral circuit transistor TR1 and the second peripheral circuit transistor TR2. In other words, the bit line contact BC may be directly connected to a line that constitutes the CMOS device. The bit line contact BC may be a penetration electrode connecting the first and second peripheral circuit transistors TR1 and TR2, and the bit line BL. The bit line contacts BC may be disposed spaced apart from the first peripheral source/drain regions 29a, the impurity region 22, and the second peripheral source/drain regions 29b of the first and second peripheral circuit transistors TR1 and TR2.

First spacers 132 may be disposed conformally surrounding side surfaces of the bit line contacts BC. Lower surfaces of the first spacers 132 may be in contact with upper surfaces of the bit lines BL. That is, the first spacers 132 may not surround lowermost ends of the bit line contacts BC. The lowermost ends of the bit line contacts BC may at least partially extend into the bit lines BL to be in contact with the bit line BL. The bit line contacts BC may be electrically isolated from the peripheral substrate 10 by the first spacers 132. The first spacers 132 may be disposed in contact with or spaced apart from the first peripheral source/drain regions 29a, the impurity region 22, and the second peripheral source/drain regions 29b of the first and second peripheral circuit transistors TR1 and TR2. The bit line contacts BC may be electrically isolated from the first and second peripheral circuit transistors TR1 and TR2 by the first spacers 132.

The peripheral circuit transistors TR1 and TR2 may be partially connected to the back-gate line BGL. A back-gate contact BGC may be disposed extending through the peripheral substrate 10, the first interlayer insulating film 130, the second insulating pattern 123, and the back-gate capping pattern 111 to be connected to the back-gate line BGL. Unlike what is illustrated, a width of the back-gate contact BGC in the horizontal direction D1 or D2 may increase in the vertical direction D3 getting farther from the substrate 100. A lower surface of the back-gate contact BGC may be lower than an upper surface of the back-gate line BGL. The back-gate contact BGC may be provided in plurality, and the back-gate contacts BGC may be connected to the corresponding back-gate lines BGL. The back-gate contact BGC may be disposed on the cell array region CAR of the substrate 100. In a plan view, the back-gate contact BGC may vertically overlap a region between the data storage patterns DSP. That is, the back-gate contact BGC may be disposed in a region vertically overlapping a region in which the data storage patterns DSP are present in an array form. In addition, the back-gate contact BGC may be partially electrically connected to the peripheral circuit transistors TR1 and TR2. The back-gate contact BGC may be a penetration electrode connecting the first and second peripheral circuit transistors TR1 and TR2 and the back-gate line BGL.

A second spacer 133 conformally surrounding a side surface of the back-gate contact BGC may be disposed. A lower surface of the second spacer 133 may be in contact with upper surfaces of the back-gate line BGL and the back-gate insulating patterns 110. That is, the second spacer 133 may not surround a lowermost end of the back-gate contact BGC. The lowermost end of the back-gate contact BGC may at least partially extend into the back-gate line BGL to be in contact with the back-gate line BGL. The back-gate contact BGC may be electrically isolated from the peripheral substrate 10 by the second spacer 133.

A word line contact extending through the peripheral substrate 10, the first interlayer insulating film 130, the second insulating pattern 123, and the second capping pattern 121 to be connected to the word line WL may be disposed. The word line contact may be provided in plurality, and the word line contacts may be connected to the corresponding word lines WL. The word line contact may be disposed on the cell array region CAR of the substrate 100. In a plan view, the word line contact may vertically overlap the data storage pattern DSP. The word line contact may be disposed in a region vertically overlapping a region in which the data storage patterns DSP are present in an array form. The word line contact may be a penetration electrode connecting the first and second peripheral circuit transistors TR1 and TR2 and the word lines WL.

A spacer conformally surrounding a side surface of the word line contact may be disposed. The word line contact may be electrically isolated from the peripheral substrate 10 by the spacer.

For example, the word line contact, the bit line contact BC, and the back-gate contact BGC may include a conductive material such as metal. The first spacer 132 and the second spacer 133 may include an insulating material such as silicon oxide, silicon nitride, and/or silicon oxynitride.

In a DRAM having a vertical channel transistor VCT, an extension region may be used so as to connect the word line WL and the bit line BL to a core element that drives the word line WL and the bit line BL. That is, the word line WL and the bit line BL may extend to the extension region, and then a contact may be formed in the extension region. Accordingly, additional layers are used to form long lines, resulting in an increase of a size of the semiconductor device and further deteriorating electrical characteristics and reliability due to such additional layers for the long lines.

According to implementations, the word line contact, the bit line contact BC, and the back-gate contact BGC respectively connected to the word line WL, the bit line BL, and the back-gate line BGL may be disposed in the cell array region CAR. That is, the lines for connecting the word line WL, the bit line BL, and the back-gate line BGL to the core element for driving the same may not be formed in the extension region. Accordingly, the extension region and the additional line layers for the long line may not be formed, and thus there are advantageous effects that the size of the semiconductor device may be reduced, and the manufacturing cost of the semiconductor device may be also reduced. In addition, there is an additional effect that electrical characteristics and reliability are improved by reducing the additional lines for the long line. In addition, implementations are not limited to the DRAM having the vertical channel transistor VCT.

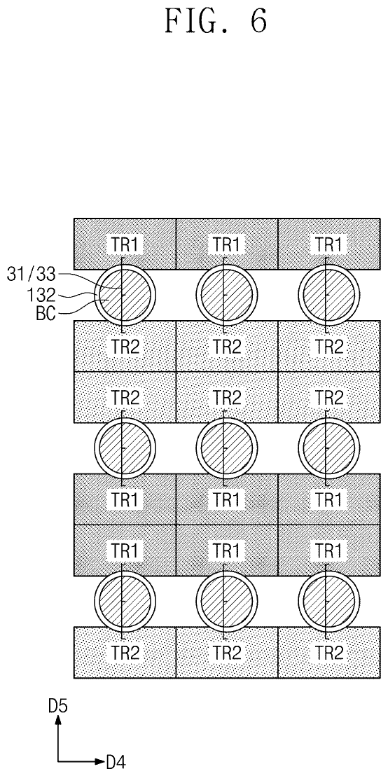

Hereinafter, a planar arrangement of the bit line contacts BC will be described in more detail. FIGS. 6 to 12 are schematic plan views for describing arrangement of penetration electrodes and transistors of a peripheral circuit structure. FIGS. 6 to 12 illustrate an arrangement of first peripheral circuit transistor TR1, second peripheral circuit transistor TR2, and bit line contacts BC, when the semiconductor device of FIGS. 3 to 5 is viewed from above. A fourth direction D4 and a fifth direction D5 in FIGS. 6 to 12 are directions parallel to an upper surface of a substrate 100 and crossing each other.

Referring to FIG. 6, the first peripheral circuit transistors TR1 may have a plurality of first columns extending along the fourth direction D4. The plurality of first columns may be arranged along the fifth direction D5. The first peripheral circuit transistors TR1 in one first column may be arranged along the fourth direction D4.

The second peripheral circuit transistors TR2 may have a plurality of second columns extending along the fourth direction D4. The plurality of second columns may be arranged along the fifth direction D5. The second peripheral circuit transistors TR2 in one second column may be arranged along the fourth direction D4. According to some implementations, the second peripheral circuit transistors TR2 adjacent to each other may share the impurity region 22 described with reference to FIG. 3.

The first columns of the first peripheral circuit transistors TR1 and the second columns of the second peripheral circuit transistors TR2 may be alternately disposed two by two along the fifth direction D5.

A pair of the first peripheral circuit transistor TR1 and the second peripheral circuit transistor TR2 adjacent to each other in the fifth direction D5 may be connected to each other through the peripheral contact plugs 31 and the peripheral circuit lines 33. The pair of the first and second peripheral circuit transistors TR1 and TR2 may constitute a CMOS device.

Each of the bit line contacts BC may be disposed between the first and second peripheral circuit transistors TR1 and TR2.

Describing with reference to the pair of first and second peripheral circuit transistors TR1 and TR2, the peripheral circuit line 33 may extend from above the first peripheral circuit transistor TR1 through above the bit line contact BC to above the second peripheral circuit transistor TR2. Described differently, the bit line contact BC may be directly connected to the peripheral circuit lines 33 connecting the first and second peripheral circuit transistors TR1 and TR2.

According to implementations, the bit line contact BC may be directly connected to the peripheral circuit lines 33 connecting the first and second peripheral circuit transistors TR1 and TR2. Accordingly, a length of electrical connection between the first and second peripheral circuit transistors TR1 and TR2 and the bit line contact BC may be small. In addition, the first and second peripheral circuit transistors TR1 and TR2 and the bit line contact BC may be disposed on the cell array region CAR of the cell structure CS, and the bit line contact BC may be directly connected to the bit line BL. The bit line BL of the cell structure CS and a CMOS device constituted by the first and second peripheral circuit transistors TR1 and TR2 of the peripheral circuit structure PS may be connected through the bit line contact BC. That is, in a line structure connecting the bit line BL and the CMOS device, there may be a few or no horizontal lines, and only the bit line contact BC may be provided as a vertical line. A length of electrical connection between the cell structure CS and the peripheral circuit structure PS may be small. That is, the semiconductor device with improved electrical characteristics may be provided.

In addition, since the bit line contact BC is disposed between the first and second peripheral circuit transistors TR1 and TR2 of the CMOS device, a separate space for connecting the cell structure CS and the peripheral circuit structure PS may not be needed. That is, the semiconductor device with a small size may be provided.

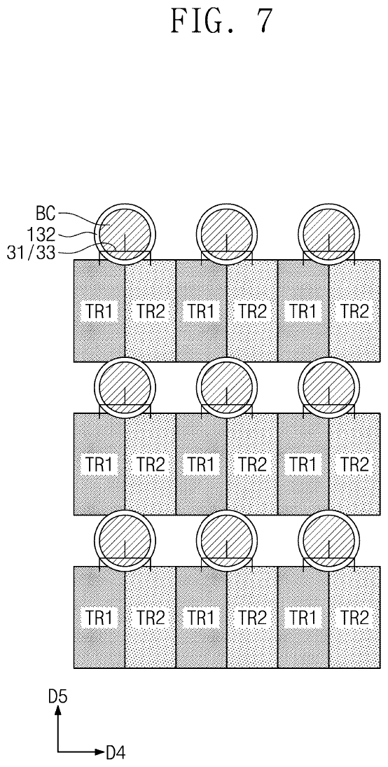

According to other implementations, as illustrated in FIG. 7, the first peripheral circuit transistors TR1 and the second peripheral circuit transistors TR2 may have a plurality of third columns extending along the fourth direction D4. The plurality of third columns may be arranged spaced apart from each other along the fifth direction D5. The first peripheral circuit transistors TR1 and the second peripheral circuit transistors TR2 in one third column may be alternately arranged along the fourth direction D4.

The pair of the first peripheral circuit transistor TR1 and the second peripheral circuit transistor TR2 adjacent to each other in the fourth direction D4 may be connected to each other through the peripheral contact plugs 31 and the peripheral circuit lines 33. The pair of the first and second peripheral circuit transistors TR1 and TR2 may constitute a CMOS device.

Each of the bit line contacts BC may be disposed adjacent to each pair of the first and second peripheral circuit transistors TR1 and TR2 in the fifth direction D5. The bit line contacts BC may be disposed between columns respectively composed of the first peripheral circuit transistors TR1 and the second peripheral circuit transistors TR2.

Describing with reference to the pair of first and second peripheral circuit transistors TR1 and TR2, the peripheral circuit line 33 may extend from above the first peripheral circuit transistor TR1 to above the second peripheral circuit transistor TR2. The peripheral circuit lines 33 may extend from above the first and second peripheral circuit transistors TR1 and TR2 to above the bit line contact BC along fifth direction D5.

According to implementations, the bit line contact BC may be disposed adjacent to the first and second peripheral circuit transistors TR1 and TR2, and a length of electrical connection between the first and second peripheral circuit transistors TR1 and TR2 and the bit line contact BC may be small.

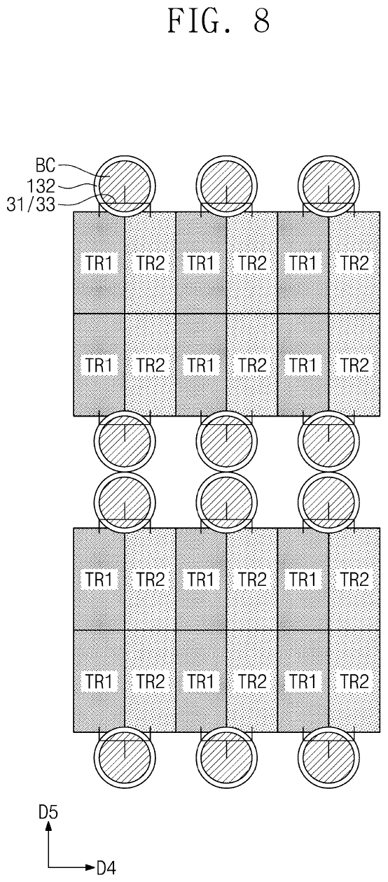

Unlike what is illustrated in FIG. 7, as illustrated in FIG. 8, the first peripheral circuit transistors TR1 and the second peripheral circuit transistors TR2 may have the plurality of third columns extending along the fourth direction D4. The first peripheral circuit transistors TR1 and the second peripheral circuit transistors TR2 in one third column may be alternately arranged along the fourth direction D4. Each of the third columns may be adjacent to another third column in the fifth direction D5. One column of the adjacent third columns will be referred to as a first sub-column, and the other column thereof in the fifth direction D5 will be referred to as a second sub-column. When a pair of the first sub-column and the second sub-column is defined as one column group, the column groups may be arranged to be spaced apart from each other along the fifth direction D5. According to some implementations, the second peripheral circuit transistors TR2 adjacent to each other may share the impurity region 22 described with reference to FIG. 3.

The pair of the first peripheral circuit transistor TR1 and the second peripheral circuit transistor TR2 adjacent to each other in the fourth direction D4 may be connected to each other through the peripheral contact plugs 31 and the peripheral circuit lines 33. The pair of the first and second peripheral circuit transistors TR1 and TR2 may constitute a CMOS device.

Each of the bit line contacts BC may be disposed adjacent to each pair of the first and second peripheral circuit transistors TR1 and TR2 in the fifth direction D5. For example, the bit line contact BC connected to the first and second peripheral circuit transistors TR1 and TR2 of the first sub-column may be located in the fifth direction D5 of the first sub-column. For example, the bit line contact BC connected to the first and second peripheral circuit transistors TR1 and TR2 of the second sub-column may be located in the opposite direction of the fifth direction D5 of the second sub-column. The bit line contact BC may be disposed between the column groups.

Describing with reference to the pair of first and second peripheral circuit transistors TR1 and TR2, the peripheral circuit line 33 may extend from above the first peripheral circuit transistor TR1 to above the second peripheral circuit transistor TR2. The peripheral circuit lines 33 may extend from above the first and second peripheral circuit transistors TR1 and TR2 to above the bit line contact BC along fifth direction D5.

According to implementations, the bit line contact BC may be disposed adjacent to the first and second peripheral circuit transistors TR1 and TR2, and a length of electrical connection between the first and second peripheral circuit transistors TR1 and TR2 and the bit line contact BC may be small.

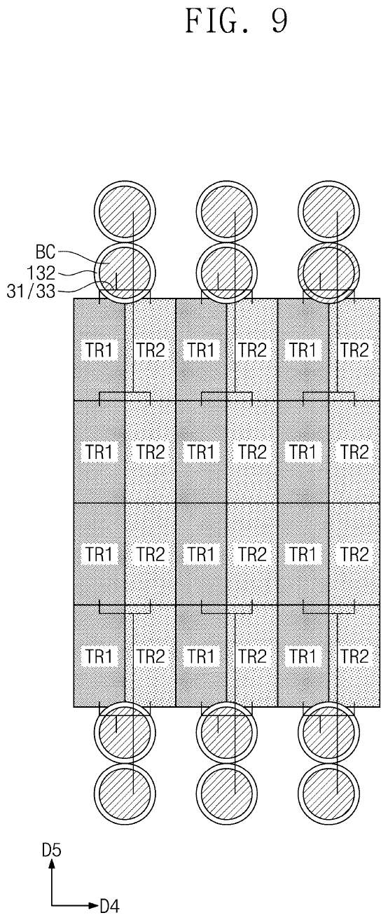

Unlike what is illustrated in FIG. 8, as illustrated in FIG. 9, the first peripheral circuit transistors TR1 and the second peripheral circuit transistors TR2 may have the plurality of third columns extending along the fourth direction D4. The first peripheral circuit transistors TR1 and the second peripheral circuit transistors TR2 in one third column may be alternately arranged along the fourth direction D4. The third columns may be adjacent to each other in the fifth direction D5. The third columns adjacent to each other may be defined as one column group. According to implementations of FIG. 9, the first and second peripheral circuit transistors TR1 and TR2 illustrated therein may be included in one column group. According to implementations, the second peripheral circuit transistors TR2 adjacent to each other may share the impurity region 22 described with reference to FIG. 3.

The pair of the first peripheral circuit transistor TR1 and the second peripheral circuit transistor TR2 adjacent to each other in the fourth direction D4 may be connected to each other through the peripheral contact plugs 31 and the peripheral circuit lines 33. The pair of the first and second peripheral circuit transistors TR1 and TR2 may constitute a CMOS device.

Each of the bit line contacts BC may be disposed in the fifth direction D5 of the pair of the first and second peripheral circuit transistors TR1 and TR2. For example, the bit line contacts BC may be disposed in the fifth direction D5 of the column group or the opposite direction thereof.

Describing with reference to the pair of the first and second peripheral circuit transistors TR1 and TR2, the peripheral circuit line 33 connecting the pair of the first and second peripheral circuit transistors TR1 and TR2 may extend to above the bit line contact BC along the fifth direction D5 or the opposite direction thereof.

According to other implementations, as illustrated in FIG. 10, the first peripheral circuit transistors TR1 may have a plurality of first columns extending along the fifth direction D5. The plurality of first columns may be arranged along the fourth direction D4. The first peripheral circuit transistors TR1 in one first column may be arranged along the fifth direction D5.

The second peripheral circuit transistors TR2 may have a plurality of second columns extending along the fifth direction D5. The plurality of second columns may be arranged along the fourth direction D4. The second peripheral circuit transistors TR2 in one second column may be arranged along the fifth direction D5. According to implementations, the second peripheral circuit transistors TR2 adjacent to each other may share the impurity region 22 described with reference to FIG. 3.

The first columns of the first peripheral circuit transistors TR1 and the second columns of the second peripheral circuit transistors TR2 may be alternately disposed along the fourth direction D4. One of the first columns of the first peripheral circuit transistors TR1 may be disposed adjacent to one of the second columns of the second peripheral circuit transistors TR2 and may be disposed spaced apart from another one of the second columns of the second peripheral circuit transistors TR2.

The pair of the first peripheral circuit transistor TR1 and the second peripheral circuit transistor TR2 adjacent to each other in the fourth direction D4 may be connected to each other through the peripheral contact plugs 31 and the peripheral circuit lines 33. The pair of the first and second peripheral circuit transistors TR1 and TR2 may constitute a CMOS device.

Each of the bit line contacts BC may be disposed adjacent to the pair of the first and second peripheral circuit transistors TR1 and TR2 in the fourth direction D4. The bit line contacts BC may be disposed between columns respectively composed of the first peripheral circuit transistors TR1 and the second peripheral circuit transistors TR2.

Describing with reference to the pair of first and second peripheral circuit transistors TR1 and TR2, the peripheral circuit line 33 may extend from above the first peripheral circuit transistor TR1 to above the second peripheral circuit transistor TR2. The peripheral circuit lines 33 may extend from above the first and second peripheral circuit transistors TR1 and TR2 to above the bit line contact BC along fourth direction D4.

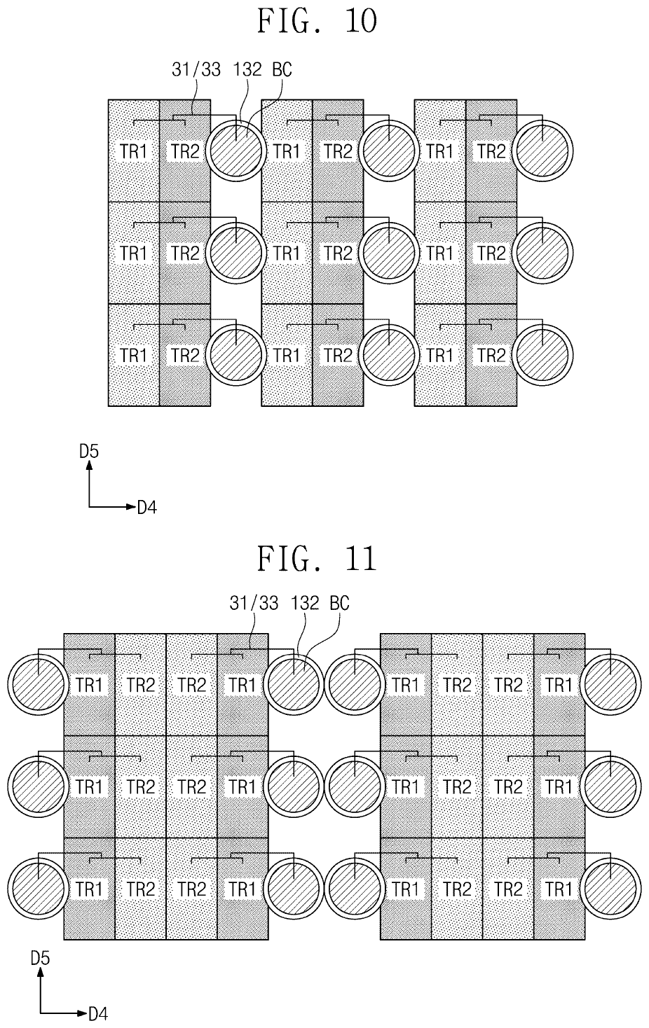

Unlike what is illustrated in FIG. 10, as illustrated in FIG. 11, the first peripheral circuit transistors TR1 may have a plurality of first columns extending along the fifth direction D5. The second peripheral circuit transistors TR2 may have a plurality of second columns extending along the fifth direction D5. In this case, four first columns and second columns, more specifically, two pairs of the first columns and the second columns may be disposed adjacent to each other in the fifth direction D5. When the four first columns and second columns are defined as one column group, the column groups may be arranged to be spaced apart from each other along the fifth direction D5. In the one column group, one of the first columns of the first peripheral circuit transistors TR1 may be disposed adjacent to one of the second columns of the second peripheral circuit transistors TR2. For example, as illustrated in FIG. 11, two second columns of the second peripheral circuit transistors TR2 may be disposed between two first columns of the first peripheral circuit transistors TR1 spaced apart from each other in the fifth direction D5.

The pair of the first peripheral circuit transistor TR1 and the second peripheral circuit transistor TR2 adjacent to each other in the fourth direction D4 may be connected to each other through the peripheral contact plugs 31 and the peripheral circuit lines 33. The pair of the first and second peripheral circuit transistors TR1 and TR2 may constitute a CMOS device.

Each of the bit line contacts BC may be disposed adjacent to the pair of the first and second peripheral circuit transistors TR1 and TR2 in the fourth direction D4 or the opposite direction thereof. The bit line contact BC may be disposed between the column groups.

Describing with reference to the pair of first and second peripheral circuit transistors TR1 and TR2, the peripheral circuit line 33 may extend from above the first peripheral circuit transistor TR1 to above the second peripheral circuit transistor TR2. The peripheral circuit lines 33 may extend from above the first and second peripheral circuit transistors TR1 and TR2 to above the bit line contact BC along fourth direction D4 or the opposite direction thereof.

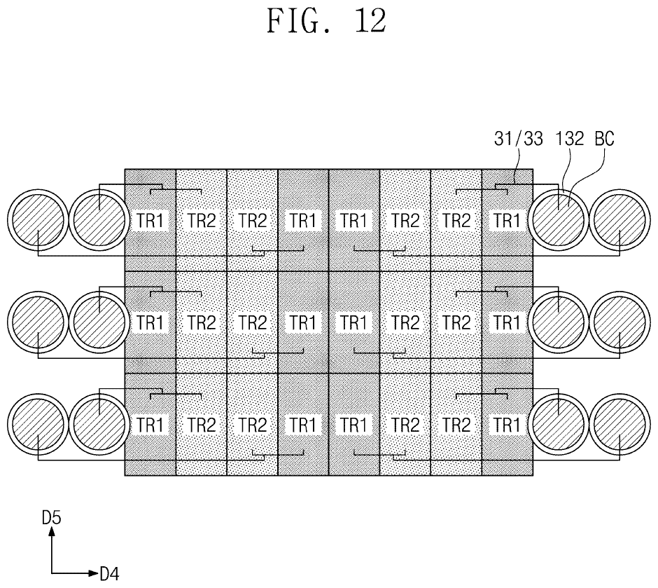

Unlike what is illustrated in FIG. 11, as illustrated in FIG. 12, the first peripheral circuit transistors TR1 may have a plurality of first columns extending along the fifth direction D5. The second peripheral circuit transistors TR2 may have a plurality of second columns extending along the fifth direction D5. The first columns and the second columns may be alternately disposed two by two, or one by one. The first columns and the second columns may be adjacent to each other in the fourth direction D4. The first columns and the second columns adjacent to each other may be defined as one column group. According to some implementations of FIG. 12, the first and second peripheral circuit transistors TR1 and TR2 illustrated therein may be included in one column group. According to some implementations, the second peripheral circuit transistors TR2 adjacent to each other may share the impurity region 22 described with reference to FIG. 3.

The pair of the first peripheral circuit transistor TR1 and the second peripheral circuit transistor TR2 adjacent to each other in the fourth direction D4 may be connected to each other through the peripheral contact plugs 31 and the peripheral circuit lines 33. The pair of the first and second peripheral circuit transistors TR1 and TR2 may constitute a CMOS device.

Each of the bit line contacts BC may be disposed in the fourth direction D4 of the pair of the first and second peripheral circuit transistors TR1 and TR2. For example, the bit line contacts BC may be disposed in the fourth direction D4 of the column group or the opposite direction thereof.

Describing with reference to the pair of the first and second peripheral circuit transistors TR1 and TR2, the peripheral circuit line 33 connecting the pair of the first and second peripheral circuit transistors TR1 and TR2 may extend to above the bit line contact BC along the fourth direction D4 or the opposite direction thereof.

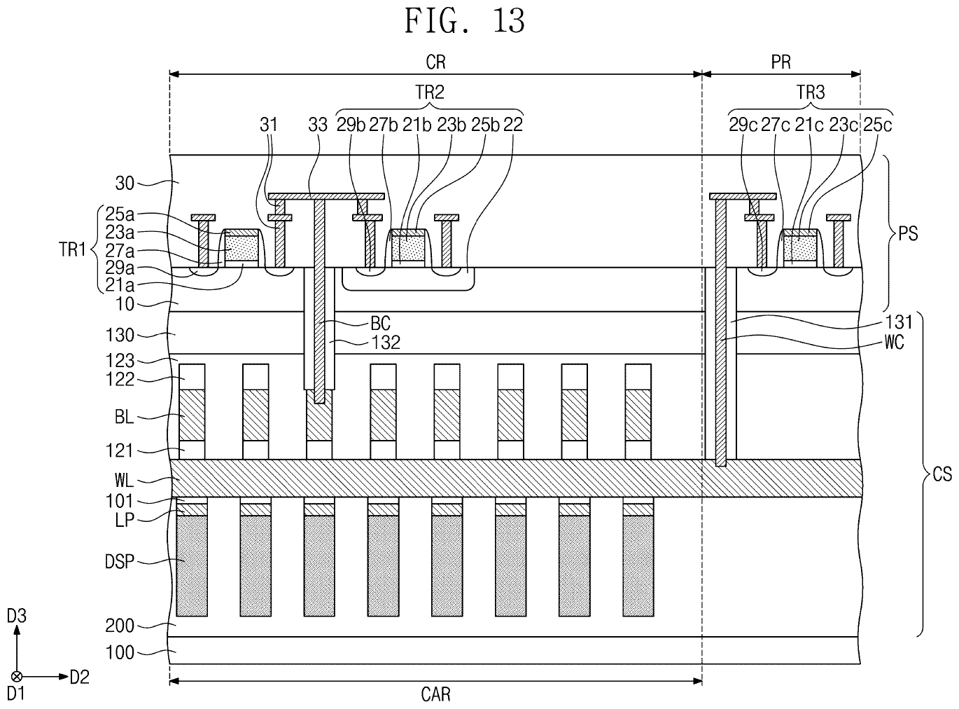

FIG. 13 is a cross-sectional view for describing a semiconductor device according to implementations.

According to implementations of FIGS. 3 to 5, it is described that the word line contact, the bit line contact BC, and the back-gate contact BGC are all disposed on the cell array region CAR of the cell structure CS, but implementations are not limited thereto.

Referring to FIG. 13, word lines WL of the cell structure CS may extend in the cell array region CAR along the second direction D2. The word lines WL may continuously extend along the second direction D2, and may extend to the outside of the cell array region CAR.

A peripheral circuit structure PS may be disposed on the cell structure CS.

A peripheral substrate of a peripheral circuit structure PS may have a first region CR overlapping the cell array region CAR and a second region PR disposed spaced apart from the first region CR. The second region PR may not vertically overlap the cell array region CAR. The first region CR may be a core region of the peripheral circuit structure PS, and the second region PR may be a peripheral region of the peripheral circuit structure PS. Hereinafter, the first region CR and the second region PR will be respectively referred to as the core region CR and the peripheral region PR.

The sense amplifier 3 and the column decoder 4 described with reference to FIG. 1 may be provided on the core region CR. For example, first and second peripheral circuit transistors TR1 and TR2 may be disposed on a peripheral substrate 10 of the core region CR. The first and second peripheral circuit transistors TR1 and TR2 may be substantially the same as or similar to those described with reference to FIGS. 3 to 12. The first and second peripheral circuit transistors TR1 and TR2 may be connected to bit lines BL through bit line contacts BC provided on the core region CR (or the cell array region CAR). Alternatively, the first and second peripheral circuit transistors TR1 and TR2 may be connected to a back-gate line BGL through a back-gate contact BGC provided on the core region CR (or the cell array region CAR).

A row decoder 2 described with reference to FIG. 1 may be provided on the peripheral region PR. For example, some transistors of the peripheral circuit structure PS may be provided on the peripheral substrate 10 on the peripheral circuit structure PS. The transistors provided on the peripheral region PR will be referred to as third peripheral circuit transistors TR3.

Each of the third peripheral circuit transistors TR3 may include a third peripheral gate insulating film 21c, a third peripheral gate electrode 23c, a third peripheral capping pattern 25c, a third peripheral gate spacer 27c, and third peripheral source/drain regions 29c. The third peripheral gate insulating film 21c may be disposed between the third peripheral gate electrode 23c and the peripheral substrate 10. The third peripheral capping pattern 25c may be disposed on the third peripheral gate electrode 23c. The third peripheral gate spacer 27c may cover sidewalls of the third peripheral gate insulating film 21c, the third peripheral gate electrode 23c, and the third peripheral capping pattern 25c. The third peripheral source/drain regions 29c may be provided inside the peripheral substrate 10 adjacent to both sides of the third peripheral gate electrode 23c.

A word line contact WC may extend through the peripheral substrate 10, a first interlayer insulating film 130, and a second insulating pattern 123 to be connected to the word line WL on the peripheral region PR. Unlike what is illustrated, a width of the word line contact WC in the horizontal direction D1 or D2 may increase in the third direction D3 getting farther from the substrate 100. A lower surface of the word line contact WC may be lower than an upper surface of the word line WL. The word line contact WC may be provided in plurality, and the word line contacts WC may be respectively connected to the corresponding word lines WL. The word line contact WC may be disposed on the peripheral region PR of the peripheral substrate 10. In a plan view, the word line contact WC may be horizontally spaced apart from the cell array region CAR, more preferably, from the data storage patterns DSP. The word line contact WC may extend through the peripheral circuit insulating film 30 to be connected to the peripheral circuit lines 33 connected to the third peripheral circuit transistor TR3. The word line contact WC may be a penetration electrode connecting the third peripheral circuit transistor TR3 and the word line WL.

A third spacer 131 conformally surrounding side surfaces of the word line contact WC may be disposed. A lower surface of the third spacer 131 may be in contact with upper surfaces of the word lines WL. That is, the third spacer 131 may not surround lowermost ends of the word line contacts WC. The lowermost end of the word line contact WC may at least partially extend into the word line WL to be in contact with the word line WL. The word line contact WC may be electrically isolated from the peripheral substrate 10 by the third spacer 131.

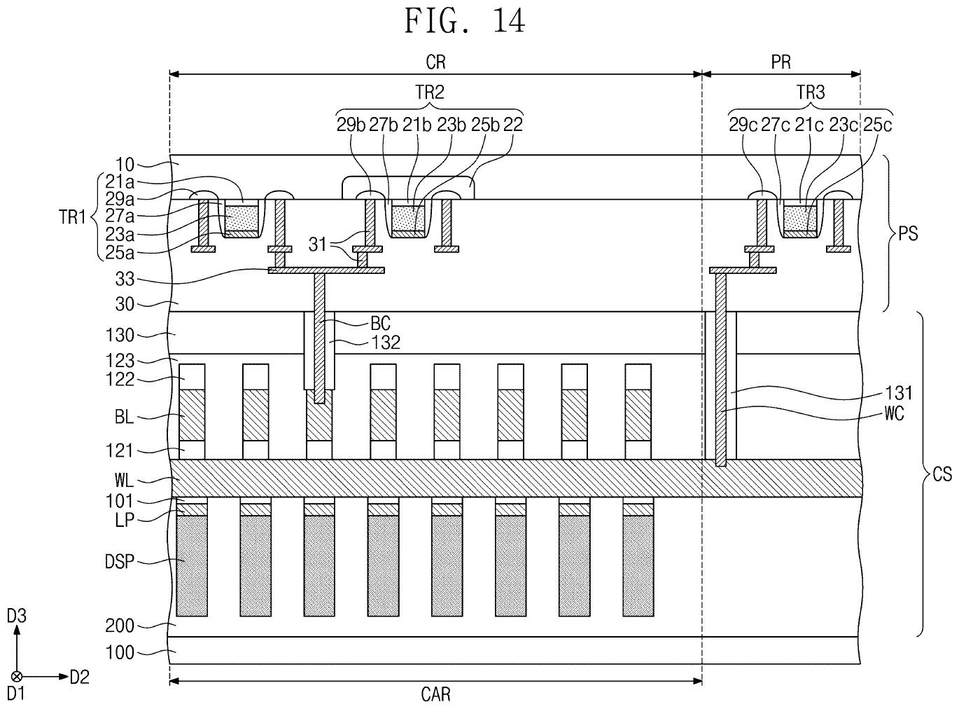

FIG. 14 is a cross-sectional view for describing a semiconductor device according to implementations.

Referring to FIG. 14, a cell structure CS may be disposed on a substrate 100, and a peripheral circuit structure PS may be disposed on the cell structure CS. The cell structure CS may be substantially the same as that described with reference to FIG. 3 to 5 or 13.

The peripheral circuit structure PS may include peripheral circuit transistors TR1 and TR2 on a lower surface of a peripheral substrate 10, peripheral contact plugs 31, and peripheral circuit lines 33 electrically connected to the peripheral circuit transistors TR1 and TR2 through the peripheral contact plugs 31. The peripheral circuit transistors TR1 and TR2 may be substantially the same as those described with reference to FIG. 3 to 5 or 13.

A peripheral circuit insulating film 30 may be disposed on a lower surface of the peripheral substrate 10. The peripheral circuit insulating film 30 may cover the first and second peripheral circuit transistors TR1 and TR2, the peripheral contact plugs 31, and the peripheral circuit lines 33. The peripheral circuit insulating film 30 may be in contact with the first interlayer insulating film 130.

A bit line contact BC may extend through the peripheral circuit insulating film 30, the first interlayer insulating film 130, and a capping layer 122, and partially extend through the second insulating pattern 123 to be connected to the bit line BL. In a plan view, each of the bit line contacts BC may be disposed between a pair of first and second peripheral circuit transistors TR1 and TR2 electrically connected to each other. First spacers 132 conformally surrounding side surfaces of the bit line contacts BC may be disposed. The first spacers 132 may be interposed between the bit line contact BC and the first interlayer insulating film 130 and between the bit line contact BC and the second insulating pattern 123. According to some implementations, the first spacers 132 may not be provided.

In a semiconductor device according to implementations, a word line contact, a bit line contact, and a back-gate contact respectively connected to a word line, a bit line, and a back-gate line may be disposed in a cell array region. That is, lines for connecting the word line, the bit line, and the back-gate line to a core element for driving the same may not be separately formed in an extension region. Accordingly, the extension region and additional line layers may not be formed, and thus there are advantageous effects that a size of the semiconductor device may be reduced, and manufacturing cost of the semiconductor device may be also reduced. In addition, there is an effect that electrical characteristics and reliability are improved by reducing the additional lines.

In addition, the bit line contact may be directly connected to a peripheral circuit line connecting peripheral circuit transistors. Accordingly, a length of electrical connection between the peripheral circuit transistors and the bit line contact may be small. The peripheral circuit transistors and the bit line contact may be disposed on a cell array region of a cell structure, and the bit line contact may be directly connected to the bit line. That is, in a lining structure connecting the bit line and a CMOS device, there may be a few or no horizontal lines, and only the bit line contact, which is a vertical line, may be provided. A length of electrical connection between the cell structure and a peripheral circuit structure may be small. That is, the semiconductor device with improved electrical characteristics may be provided.

In addition, since the bit line contact is disposed between first and second peripheral circuit transistors of the CMOS device, a separate space for connecting the cell structure and the peripheral circuit structure may not be needed. That is, the semiconductor device with a small size may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present invention have been described, it is understood that the present invention should not be limited to these implementations but various changes and modifications can be made by one ordinary skilled in the art within the spirit and scope of the present invention as hereinafter claimed.

What is claimed is:

1. A semiconductor device comprising:
a cell structure; and
a peripheral circuit structure disposed on the cell structure,
wherein the cell structure includes:
a first substrate having a cell array region;
data storage patterns on the cell array region, the data storage patterns being spaced apart from each other in a first direction and a second direction, the first direction and the second direction being parallel to an upper surface of the first substrate and crossing each other;
word lines extending in the second direction on the data storage patterns, and spaced apart from each other in the first direction; and
bit lines on the word lines, the bit lines crossing the word lines, extending in the first direction, and being spaced apart from each other in the second direction,
wherein the peripheral circuit structure includes:
a second substrate having a first region and a second region spaced apart from the first region, the first region overlapping the cell array region;
first and second transistors that are on the first region and disposed on a surface of the second substrate; and
a first penetration electrode disposed between the first and second transistors, and vertically extending through the second substrate on the first region to be electrically connected to the bit lines, and
wherein the first transistors and the second transistors have different conductivity type channel regions.

2. The semiconductor device of claim 1, wherein the first transistor comprises:
an impurity region in the second substrate and contacting the surface of the second substrate;
first source/drain regions in the impurity region; and
a first gate disposed on the impurity region and located between the first source/drain regions, and
wherein the second transistor comprises:
second source/drain regions in the second substrate and spaced apart from the impurity region; and
a second gate disposed on the surface of the second substrate and located between the second source/drain regions.

3. The semiconductor device of claim 2, wherein the first penetration electrode is spaced apart from the impurity region, the first source/drain regions, and the second source/drain regions.

4. The semiconductor device of claim 1, wherein the peripheral circuit structure comprises a spacer interposed between the first penetration electrode and the second substrate, and
the first penetration electrode is electrically insulated from the second substrate by using the spacer.

5. The semiconductor device of claim 1, wherein the peripheral circuit structure further comprises a peripheral circuit line that is disposed on the second substrate and connects the first transistor and the second transistor, and
the first penetration electrode is connected to the peripheral circuit line.

6. The semiconductor device of claim 5, wherein the peripheral circuit line is located on the first transistor and the second transistor.

7. The semiconductor device of claim 1, wherein the first transistor includes a plurality of first transistors, and the second transistor includes a plurality of second transistors,
the first penetration electrode includes a plurality of first penetration electrodes, and
the plurality of first penetration electrodes electrically connect the plurality of first transistors and the plurality of second transistors to the cell structure.

8. The semiconductor device of claim 7, wherein each of the plurality of first penetration electrodes is disposed between one of the plurality of first transistors and one of the plurality of second transistors that are electrically connected to each other.

9. The semiconductor device of claim 7, wherein one of the plurality of first transistors and one of the plurality of second transistors are electrically connected to each other, and
wherein the plurality of first penetration electrodes are disposed between (i) a first pair of one of the plurality of first transistors and one of the plurality of second transistors and (ii) a second pair of one of the plurality of first transistors and one of the plurality of second transistors electrically connected to each other.

10. The semiconductor device of claim 1, wherein the peripheral circuit structure further comprises:
a third transistor on the second region, the third transistor being disposed on the surface of the second substrate; and
a second penetration electrode vertically extending through the second substrate on the second region to be electrically connected to the word lines.

11. A semiconductor device comprising:
a cell structure; and
a peripheral circuit structure disposed on the cell structure,
wherein the cell structure includes:
a first substrate;
data storage patterns on the first substrate, the data storage patterns being spaced apart from each other in a first direction and a second direction, the first direction and the second direction being parallel to an upper surface of the first substrate and crossing each other;
word lines extending in the second direction on the data storage patterns, and spaced apart from each other in the first direction; and
bit lines on the word lines, the bit lines crossing the word lines, extending in the first direction and being spaced apart from each other in the second direction,
wherein the peripheral circuit structure includes:
a second substrate;
a first transistor and a second transistor that are disposed on a surface of the second substrate;
a first penetration electrode disposed between the first and second transistors, and vertically extending through the second substrate to be electrically connected to the bit lines; and
a spacer interposed between the second substrate and the first penetration electrode,
wherein the first transistor includes:
an impurity region formed in the second substrate so as to be in contact with the surface of the second substrate; and
first source/drain regions formed in the impurity region, and
wherein the first penetration electrode is spaced apart from the impurity region.

12. The semiconductor device of claim 11, wherein the cell structure further comprises semiconductor patterns electrically connected to the data storage patterns,
wherein the semiconductor patterns each extend in a direction vertical to an upper surface of the first substrate,
the semiconductor patterns and the data storage patterns are disposed on a cell array region of the first substrate,
the first transistor and the second transistor are disposed on a core region of the second substrate,
the first penetration electrode is disposed in the core region, and
the core region vertically overlaps the cell array region.

13. The semiconductor device of claim 12, wherein the second substrate further comprises a peripheral region spaced apart from the core region, and
the peripheral circuit structure further comprises:
a third transistor, on the peripheral region, disposed on the surface of the second substrate; and
a second penetration electrode vertically extending through the second substrate on the peripheral region to be electrically connected to the word lines.

14. The semiconductor device of claim 11, wherein the first transistor and the second transistor have different conductivity type channel regions.

15. The semiconductor device of claim 14, wherein the second transistor comprises second source/drain regions formed in the second substrate, and disposed so as to be spaced apart from the impurity region.

16. The semiconductor device of claim 11, wherein the spacer is spaced apart from the impurity region.

17. The semiconductor device of claim 11, wherein the peripheral circuit structure further comprises a peripheral circuit line disposed on the second substrate, and connecting the first transistor and the second transistor, and
the first penetration electrode vertically overlaps the peripheral circuit line, and is connected to the peripheral circuit line.

18. The semiconductor device of claim 11, wherein the first transistor and the second transistor are each provided in plurality,
the first penetration electrode is provided in plurality, and
the plurality of first penetration electrodes are each disposed between a pair of the first transistor and the second transistor that are electrically connected to each other.

19. A semiconductor device comprising:
a cell structure; and
a peripheral circuit structure disposed on the cell structure,
wherein the cell structure includes:
a first substrate having a cell array region;
a plurality of data storage patterns on the cell array region, spaced apart from each other in a horizontal direction;
semiconductor patterns on the data storage patterns, the semiconductor patterns extending in a direction vertical to an upper surface of the first substrate;
word lines disposed on the cell array region, and disposed adjacent to the semiconductor patterns on the data storage patterns;
gate insulating patterns respectively interposed between the word lines and the semiconductor patterns; and
bit lines on the cell array region on the word lines, the bit lines crossing the word lines, and connecting to the semiconductor patterns,
the peripheral circuit structure includes:
a second substrate having a core region overlapping the cell array region;
a first transistor and a second transistor on the core region and disposed on a surface of the second substrate; and
a peripheral circuit line disposed on the second substrate, and connecting the first transistor and the second transistor,
wherein the first transistor includes an impurity region formed in the second substrate so as to be in contact with the surface of the second substrate, and first source/drain regions formed in the impurity region,
wherein the second transistor includes second source/drain regions formed in the second substrate, and disposed so as to be spaced apart from the impurity region, and
wherein the peripheral circuit structure further includes a first penetration electrode connected to the peripheral circuit line between the first transistor and the second transistor, and vertically extending through the second substrate to be electrically connected to the bit lines.

20. The semiconductor device of claim 19, wherein the first transistor and the second transistor have different conductivity type channel regions.
